(19) United States
(12) Patent Application Publication
(10) Pub. No.: US 2025/0204083 A1
(43) Pub. Date: Jun. 19, 2025

(54) OPTICAL SENSOR PACKAGE

(71) Applicant: SEMICONDUCTOR COMPONENTS INDUSTRIES, LLC, Scottsdale, AZ (US)

(72) Inventor: Weng-Jin WU, Hsinchu City (TW)

(73) Assignee: SEMICONDUCTOR COMPONENTS INDUSTRIES, LLC, Scottsdale, AZ (US)

(21) Appl. No.: 18/538,533

(22) Filed: Dec. 13, 2023

(51) Int. Cl. H01L 31/0203; H01L 31/02; H01L 31/18

(52) U.S. Cl. CPC H10F 77/50; H10F 71/00; H10F 71/137; H10F 77/933

(57) ABSTRACT

An optical sensor module includes a transparent lid spaced apart from an optical sensor die by a protective dam. The protective dam can be formed from an insulating material that blocks moisture and contaminants from reaching the optical sensor die. The protective dam can be formed as a notched or grooved recess that extends into the substrate at a designated singulation point and forms a support for the transparent lid. The transparent lid protects the optical sensor die while permitting light to pass through and reach the optical sensors. In some implementations, the optical sensor die is surrounded by an air cavity. A solder mask with a redistribution layer protects a lower surface of the substrate. The solder mask may wrap around the substrate, or a planar solder mask can be used.

### TECHNICAL FIELD

This description relates to assembling and packaging semiconductor device modules, semiconductor device assemblies, and semiconductor devices. More specifically, this description relates to a semiconductor device module that includes an optical sensor.

### BACKGROUND

Semiconductor device assemblies, such as assemblies including optical sensors, can be implemented using one or more semiconductor dies, one or more substrates, and electrical interconnections within a package. A molding compound can be used as an encapsulant to protect components of a semiconductor device assembly.

### SUMMARY

In some aspects, the techniques described herein relate to an apparatus, including: a photodetector on a substrate; a transparent lid spaced apart from the photodetector by a gap; a notch formed in an upper surface of the substrate; a plurality of electrical contacts coupled to a lower surface of the substrate; a through-silicon via being used to electrically couple the photodetector to the plurality of electrical contacts; a solder mask in contact with a lower surface of the silicon substrate; and an insulating material disposed between the transparent lid and the silicon substrate, the insulating material filling the notch to form a dam.

In some aspects, the techniques described herein relate to a method, including: forming a photosensor on a silicon substrate; forming notches in a top surface of the silicon substrate at designated singulation points; filling the notches with an insulating material; extending a height of the insulating material above the top surface; bonding a cover glass to the insulating material to form a bonded structure; forming a through-silicon via in the silicon substrate; forming a re-distribution layer in contact with the silicon substrate; forming a plurality of electrical contacts coupled to the re-distribution layer and electrically coupling the plurality of electrical contacts to the photosensor by the through-silicon via; and singulating the bonded structure based on the designated singulation points.

In some aspects, the techniques described herein relate to a method, including: pre-scoring a photosensor package by forming a recess in a silicon substrate; disposing a moisture barrier in the recess; and singulating the photosensor package from the silicon substrate.

### BRIEF DESCRIPTION OF THE DRAWINGS

FIG. 1 is a cross-sectional view of an optical sensor module that includes a notched protective dam, an air cavity, and a wrap-around solder mask, according to an implementation of the present disclosure.

FIG. 2 is a cross-sectional view of an optical sensor module that includes a notched protective dam, an air cavity, and a planar solder mask, according to an implementation of the present disclosure.

FIG. 3 is a cross-sectional view of an optical sensor module that includes a grooved protective dam, an air cavity, and a wrap-around solder mask, according to an implementation of the present disclosure.

FIG. 4 is a cross-sectional view of an optical sensor module that includes a grooved protective dam, an air cavity, and a planar solder mask, according to an implementation of the present disclosure.

FIG. 5 is a cross-sectional view of an optical sensor module that includes a planar protective dam and a wrap-around solder mask, according to an implementation of the present disclosure.

FIG. 6 illustrates the optical sensor modules shown in FIGS. 1-5 for comparison, according to implementations of the present disclosure.

FIG. 7 is a flow diagram illustrating a method of fabricating an optical sensor module, according to an implementation of the present disclosure.

FIGS. 8A-8E, 9A-9E, and 10A-10E are cross-sectional views that illustrate operations in the method shown in FIG. 7, according to implementations of the present disclosure.

FIG. 11 is a flow diagram illustrating a method of fabricating an optical sensor module, according to an implementation of the present disclosure.

FIGS. 12A-12E and 13A-13E are cross-sectional views that illustrate operations in the method shown in FIG. 11, according to an implementation of the present disclosure.

Aspects of the present disclosure are best understood from the following detailed description when read with the accompanying figures. It is noted that, in accordance with common practice in the industry, various features are not necessarily drawn to scale. Dimensions of the various features may be arbitrarily increased or reduced for clarity of discussion. In the drawings, like reference symbols may indicate like and/or similar components (elements, structures, etc.) in different views. The drawings illustrate generally, by way of example, but not by way of limitation, various implementations discussed in the present disclosure. Reference symbols shown in one drawing may not be repeated for the same, and/or similar elements in related views. Reference symbols that are repeated in multiple drawings may not be specifically discussed with respect to each of those drawings but are provided for context between related views. Also, not all like elements in the drawings are specifically referenced with a reference symbol when multiple instances of an element are illustrated.

### DETAILED DESCRIPTION

Current implementations of semiconductor device assemblies such as optical sensor modules, may have certain drawbacks. For instance, current implementations may be assembled into a chip scale package (CSP), e.g., an imager, or interstitial, ball grid array (iBGA) package, that is vulnerable to damage during chip singulation, when individual modules formed on a silicon substrate are separated in a sawing process. The CSP may also be vulnerable to moisture penetration during subsequent operation of the optical sensor module. Optical sensor modules may include a transparent lid, e.g., a glass lid, or cover glass, that is suspended above, for example, an optical sensor die (e.g., a complimentary metal-oxide-semiconductor (CMOS) image optical sensor die), forming an air cavity between the optical sensor die and the transparent lid. The transparent lid covers and protects the optical sensor die while transmitting light to a central active area of the optical sensor die. While the transparent lid protects the optical sensor die from above, the sides of a singulated optical sensor die may still remain vulnerable to moisture penetration.

This disclosure relates to implementations of semiconductor device assemblies, including optical sensors, in which the CSP includes lateral protection against breakage and moisture penetration. A protective dam can be formed into a notched or grooved recess in the substrate, and the protective dam can then be fully hardened by curing. Formation of the dam serves to pre-score the substrate at designated singulation points to reduce damage during the singulation process. In some implementations, the protective dam can be formed between the silicon substrate and the transparent lid. In some implementations, the protective dam also acts as a spacer that provides a substantially uniform gap between the optical sensor die and the transparent lid.

An encapsulated semiconductor device assembly, or chip assembly, can be referred to as a packaged device or a semiconductor device module. Semiconductor device assemblies that include optical sensors, or light sensors, can be used in a number of image-processing applications, including cameras, smart phones, video surveillance equipment, infrared imaging systems, automotive systems including light detection and ranging (LiDAR), and industrial applications.

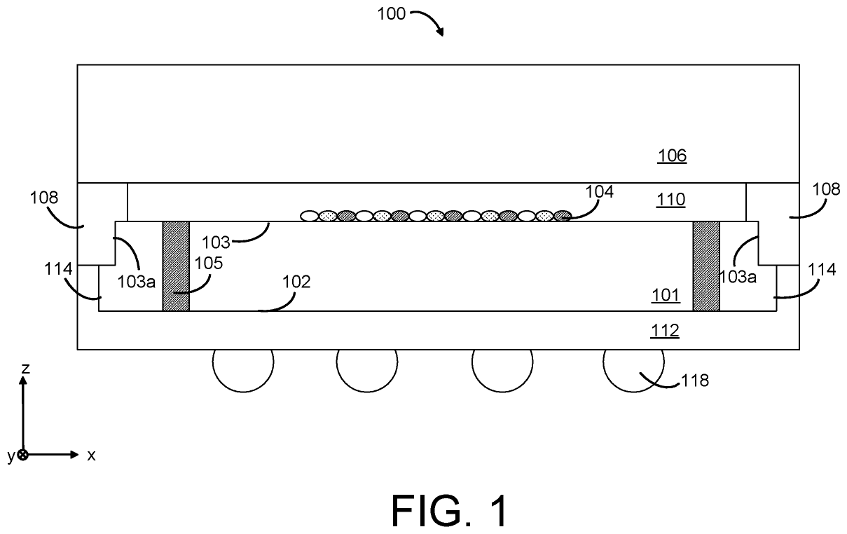

FIG. 1 is a cross-sectional view of an optical sensor module 100, in accordance with some implementations of the present disclosure. In some implementations, the optical sensor module 100 includes an optical sensor die 101 having a lower surface 102 and an upper surface 103, an active area 104, through-silicon vias 105, a transparent lid 106, a dam 108, and an air cavity 110. The optical sensor module 100 further includes packaging components such as a solder mask 112, and solder balls 118.

In some implementations, the optical sensor die 101 can include a ceramic material, a glass material, a semiconductor material, an organic material, a resin material, a laminate, or a printed circuit board. In some implementations, the optical sensor die 101 can include a portion of a semiconductor wafer having integrated circuit components such as transistors and interconnects, e.g., layers of metallization, formed therein. For example, the optical sensor die 101 can be made of, or can include silicon, silicon carbide (SiC), or III-V semiconductor materials such as gallium arsenide (GaAs), indium phosphide (InP), and so forth. In some implementations, a substrate of the optical sensor die 101 can be a glass substrate or a sapphire substrate.

In some implementations, a substrate of the optical sensor die 101, e.g., a silicon substrate, is recessed so that ends of the upper surface 103 has a stepped surface profile e.g., a notched profile 103a. In some implementations, the dam 108 covers the notched profile 103a and lower sidewalls 114 of the optical sensor die 101 are covered by the solder mask 112.

In some implementations, the optical sensor die 101 can be a semiconductor die that includes an optical sensor, that is, an image sensor that includes metal-oxide-semiconductor field effect transistors (MOSFETs) and related integrated circuit components. In some implementations, the optical sensor die 101 can be a photodetector die that has an optical side that receives light, and a sensor backside that includes circuitry that couples signals from light sensing elements on the optical side to signal processing hardware. In some implementations, the optical sensor die 101 can include an image processor, e.g., an application specific integrated circuit (ASIC). The active area 104 can be attached to, e.g., disposed on, mounted to, coupled to, or in direct contact with, the upper surface 103 of the optical sensor die 101. A central region of the optical sensor die 101 can be an active area 104, e.g., a region formed on an epitaxial layer of the optical sensor die 101. The active area 104 may include electronic components configured with photosensitive elements to sense light, e.g., reflected light from a target, or external object, that will form a digital image of the target. In some implementations, a sensor within the active area 104 can have a thickness in a range of about 100 μm to about 500 μm, and the active area 104 can have a total area in a range of about 9 mm² to about 400 mm².

Light detected by the active area 104 can be received through the transparent lid 106, which may provide environmental protection for at least the active area of the active area 104. The transparent lid 106 can be made of glass or a transparent polymer material that has suitable optical properties such as, for example, PMMA, acrylic, transparent forms of polyvinyl chloride (PVC), or similar materials. The transparent lid 106 may be generally referred to as a cover glass.

In the example shown in FIG. 1, the optical sensor die 101 can include, as internal components, an interconnect layer formed at the lower surface 102, or back side of the optical sensor die 101, and an interconnect layer formed in the upper surface 103, or front side of the optical sensor die 101. The interconnect layers may be metal layers, e.g., metal pads or patterned metal layers that form wire interconnects. For example, the upper surface 103 of the optical sensor die 101 can include an interconnect layer that provides signal paths, e.g., metal lines, or optical fiber connectors, to underlying devices. The circuitry, e.g., metallization, or interconnects, at the lower surface 102 can be coupled to a redistribution layer (RDL) in the solder mask 112. Such backside metal layers are electrically coupled by the through-silicon via (TSV) 105 so as to provide electrical connections, e.g., data transmission paths, to circuit elements on the active area 104, devices formed in the optical sensor die 101, and the solder balls 118. Devices formed in the optical sensor die 101 can include, for example, electronic devices that may process or store image information sensed by the active area 104.

The solder mask 112 is an insulating layer, e.g., a polymer, formed on the lower surface 102 of the optical sensor die 101. In some implementations, the solder mask 112 includes a redistribution layer (RDL), e.g., a metal layer, that couples electrical signals from the back side of the optical sensor die 101 and/or the through-silicon via 105 to the solder balls 118. The solder mask 112 together with the RDL form one layer. In some implementations, the solder mask 112 wraps around three sides, e.g., the lower surface 102 and lower sidewalls 114, of the optical sensor die 101. In some implementations, the solder mask 112 can have a bottom thickness in a range of about 3 μm to about 100 μm and a sidewall thickness in a range of about 1 μm to about 30 μm.

The solder mask 112 can support solder balls 118 that are in contact with the lower surface 102, e.g., a layer of metallization on the back side of the optical sensor die 101 through openings (not shown) in the solder mask 112. In some implementations, the solder balls 118 can be used to mount the optical sensor module 100 to external platforms such as a printed circuit board (PCB), a package, or to another device. In some implementations, the solder balls 118 can have a diameter in a range of about 80 μm to about 500 μm. Other means of bonding the optical sensor die 101 to such platforms can be used instead of the solder balls 118, such as, for example, direct bonding or copper pillar bumps having a bump size between about 10 μm and about 100 μm.

The dam 108 provides a lateral enclosure that protects the active area 104 and prevents moisture and contaminants from entering the air cavity 110. In the optical sensor module 100, the dam 108 fills a notched recess, that is, the dam 108 follows the contour of the notched profile 103a of the optical sensor die 101. The dam 108 therefore borders, e.g., abuts or touches, a top surface of the solder mask 112, the optical sensor die 101, the transparent lid 106, and the air cavity 110. In some implementations, the dam is made of a non-conducting material, e.g., epoxy, having a width of about 50 μm to several hundred μm, comparable to its thickness, about 10 μm to about 100 μm. The dam is disposed between the optical sensor die 101, the solder mask 112, and the transparent lid 106. In some implementations, the dam extends as much as about half the substrate thickness below the upper surface 103 of the optical sensor die 101. In the optical sensor module 100, the solder mask 112, the dam 108, and the transparent lid 106 together provide a moisture barrier to prevent moisture from entering the air cavity 110 and accessing the active area 104.

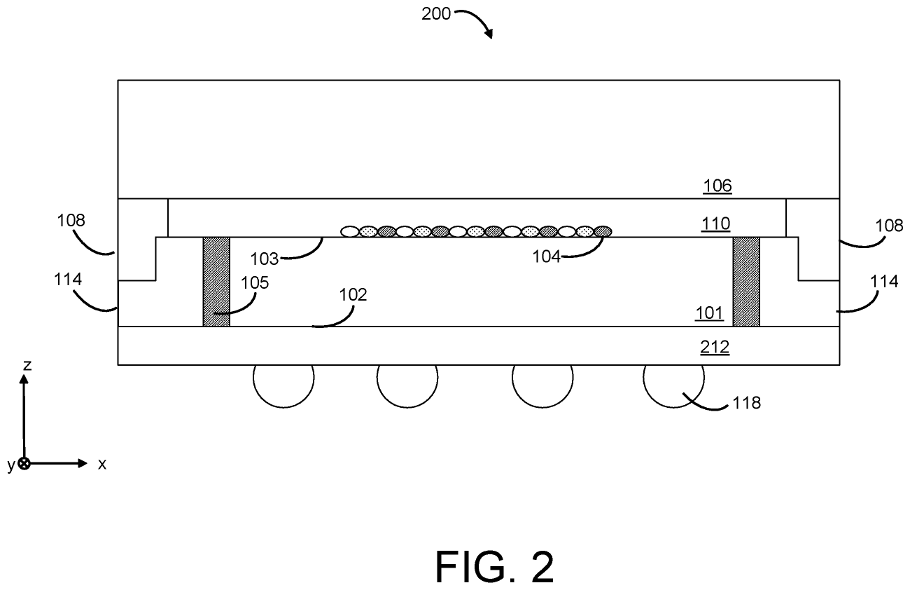

FIG. 2 is a cross-sectional view of an optical sensor module 200, in accordance with some implementations of the present disclosure. The structure shown in FIG. 2 is similar to the optical sensor module 100 shown in FIG. 1, except that a planar solder mask 212 is substituted for the wrap-around solder mask 112. Instead of wrapping around a lower portion of the optical sensor die 101 that characterizes the solder mask 112, the planar solder mask 212 is a flat structure disposed along the lower surface 102 of the optical sensor die 101. Consequently, in the optical sensor module 200, lower sidewalls 114 of the optical sensor die 101 are exposed. In the optical sensor module 200, the optical sensor die 101, the dam 108, and the transparent lid 106 together provide a moisture barrier to prevent moisture from entering the air cavity 110 and accessing the active area 104.

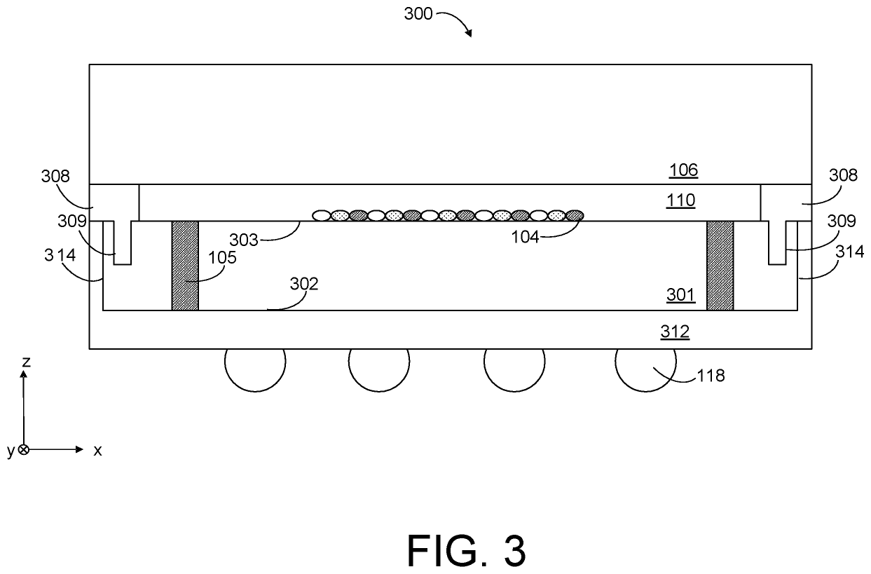

FIG. 3 is a cross-sectional view of an optical sensor module 300, in accordance with some implementations of the present disclosure. The optical sensor module 300 includes a dam 308, a wrap-around solder mask 312, and a planar optical sensor die 301 having a lower surface 302, an upper surface 303, and substrate sidewalls 314. The structure shown in FIG. 3 is similar to the optical sensor module 100 shown in FIG. 1, except that the planar optical sensor die 301 is substituted for the notched optical sensor die 101, and the dam 308 fills a grooved recess, e.g., vertical grooves 309, in the optical sensor die 301 instead of a notched recess. Extensions of the dam 308 into the vertical grooves 309, together with the upper portion of the dam 308, form an arch structure prior to singulation. In some implementations, the vertical grooves 309 can be slightly offset from outer edges of the dam 308. In some implementations, the vertical grooves 309 can be aligned with outer edges of the dam 308. Thus, instead of a stepped surface profile 103a at ends of the upper surface 103 characterizing the optical sensor die 101, the planar optical sensor die 301 instead has a flat profile along the upper surface 303 and straight sidewalls 314.

Consequently, in the optical sensor module 300, the planar optical sensor die 301 and substrate sidewalls 314 are covered by the wrap-around solder mask 312, instead of lower portions of the substrate sidewalls 314 being covered by a solder mask and upper portions of the sidewalls 314 being covered by a dam. In the optical sensor module 300, the dam 308 contacts the upper surface 303 of the planar optical sensor die 301, and a portion of the dam 308 extends into the planar optical sensor die 301 along the vertical grooves 309 by a distance up to about half the substrate thickness. In the optical sensor module 300, the wrap-around solder mask 312, the dam 308, and the transparent lid 106 together provide a moisture barrier to prevent moisture from entering the air cavity 110 and accessing the active area 104.

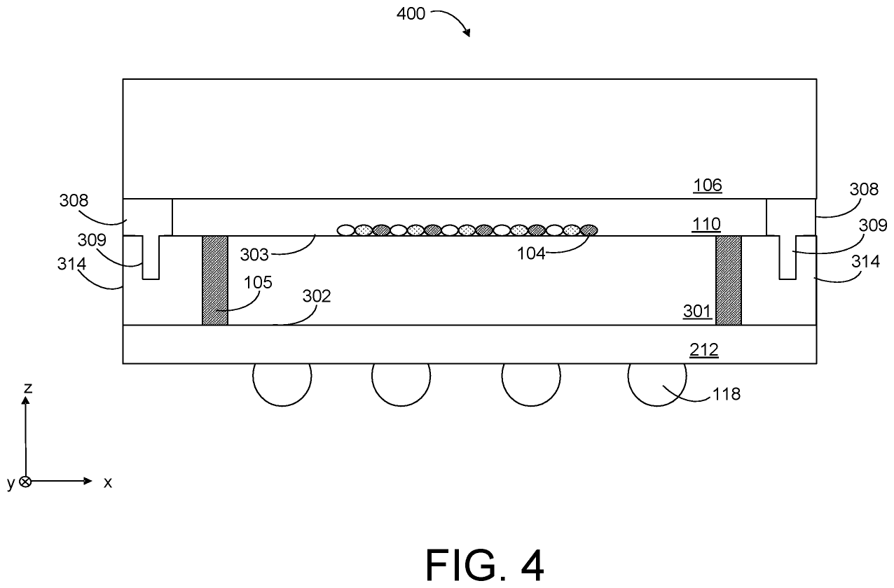

FIG. 4 is a cross-sectional view of an optical sensor module 400, in accordance with some implementations of the present disclosure. The optical sensor module 400 includes the solder mask 212, the dam 308, and the planar optical sensor die 301, including the lower surface 302, the upper surface 303, and the substrate sidewalls 314. The structure shown in FIG. 4 is similar to the optical sensor module 300 shown in FIG. 3, except that the planar solder mask 212 is substituted for the wrap-around solder mask 312. Instead of wrapping around the optical sensor die 301, the planar solder mask 212 is a flat structure disposed along the lower surface 302 of the planar optical sensor die 301. Consequently, in the optical sensor module 400, the substrate sidewalls 314 of the planar optical sensor die 301 are exposed. In the optical sensor module 400, the planar optical sensor die 301, the dam 308, and the transparent lid 106 together provide a moisture barrier to prevent moisture from entering the air cavity 110 and accessing the active area 104.

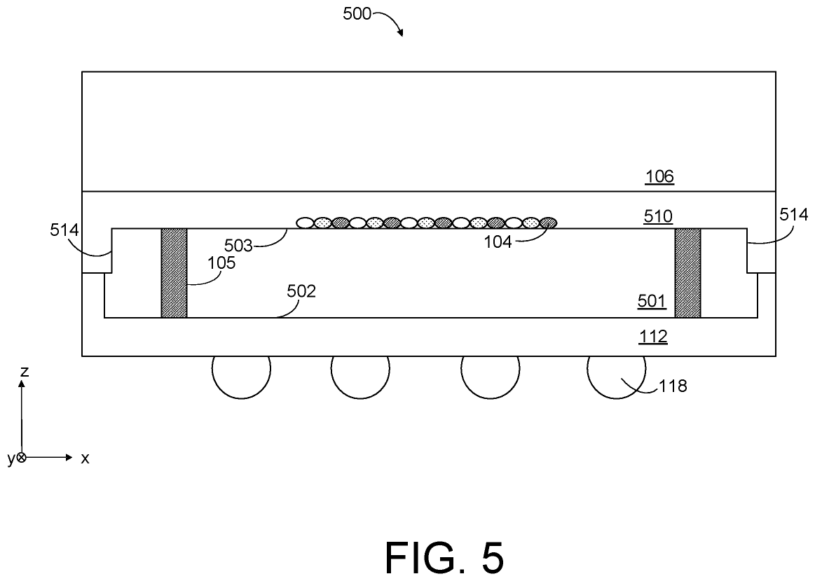

FIG. 5 is a cross-sectional view of an optical sensor module 500, in accordance with some implementations of the present disclosure. The optical sensor module 500 includes the solder mask 112, and a stepped optical sensor die 501, including a lower surface 502, an upper surface 503, and substrate sidewalls 514. The structure shown in FIG. 5 is similar to the optical sensor module 100 shown in FIG. 1, except that the optical sensor module 500 has no air cavity. Instead, the optical sensor module 500 has a dam 508 disposed between the upper surface 503 of the stepped optical sensor die 501 and the transparent lid 106. The dam 508 provides a moisture barrier that prevents moisture from accessing the active area 104. The dam 508 wraps around upper corners of the stepped optical sensor die 501 and extends down to the solder mask 112. Consequently, lower portions of the substrate sidewalls 514 are covered by the solder mask 112 and upper portions of the substrate sidewalls 514 are covered by the dam 508.

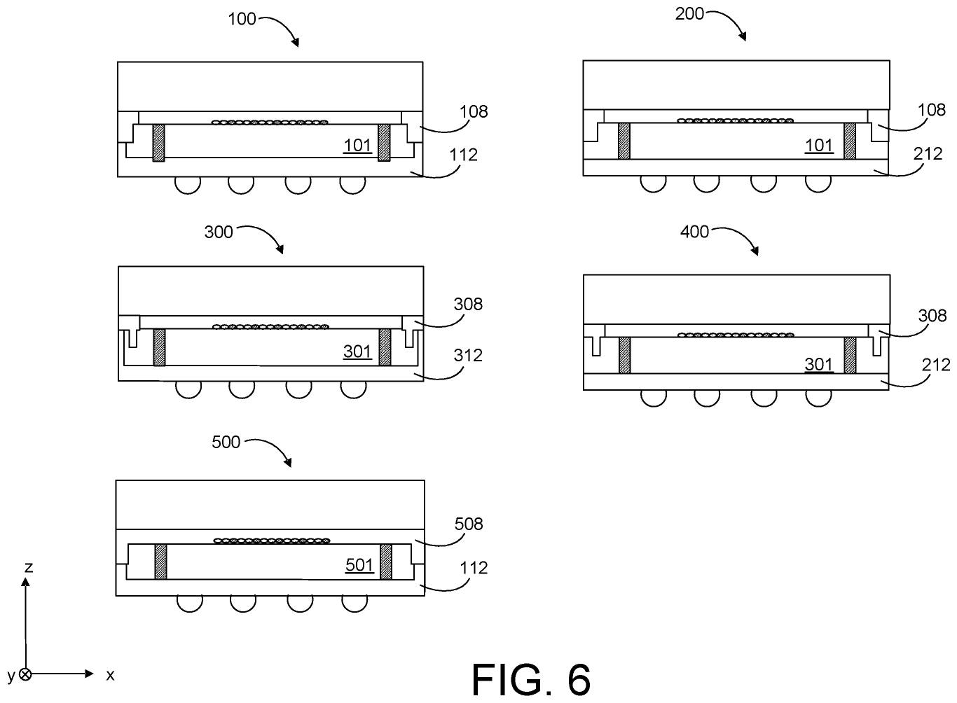

FIG. 6 provides a summary illustration of the cross-sectional views of the optical sensor modules 100, 200, 300, 400, and 500 for comparison, in accordance with some implementations of the present disclosure. The various implementations of optical sensor modules feature a T-shaped dam, e.g., the dam 108 that fills a notched recess in the optical sensor die 101; an arch-shaped dam, e.g., the dam 308 that fills a grooved recess in the planar optical sensor die 301; or an extended dam, e.g., the dam 508 that wraps around upper corners of the stepped optical sensor die 501. The various implementations of optical sensor modules also feature a wrap-around solder mask, e.g., the solder mask 112 or the solder mask 312, or a planar solder mask, e.g., the solder mask 212.

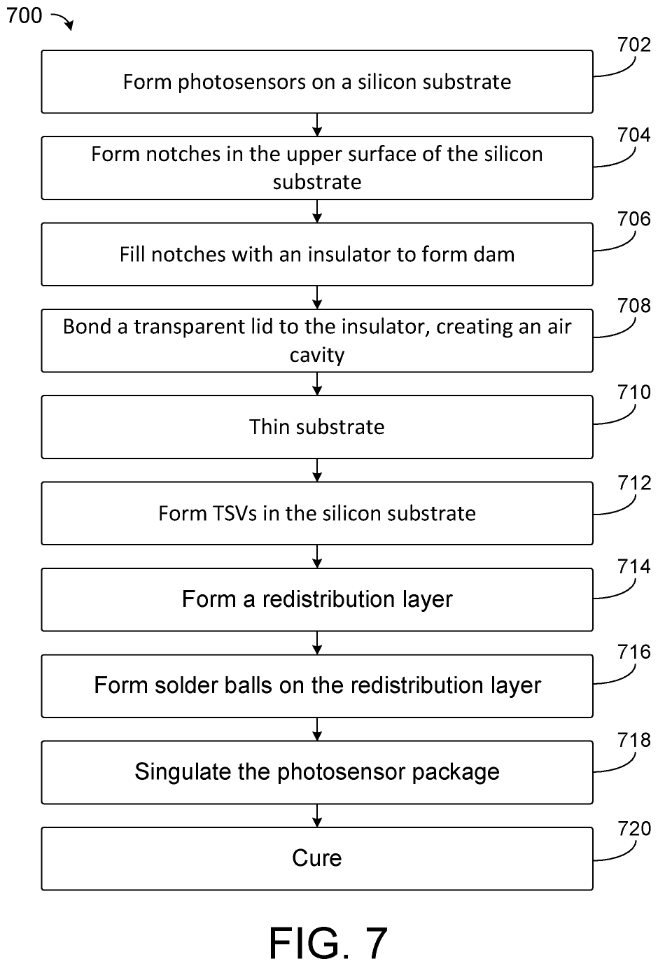

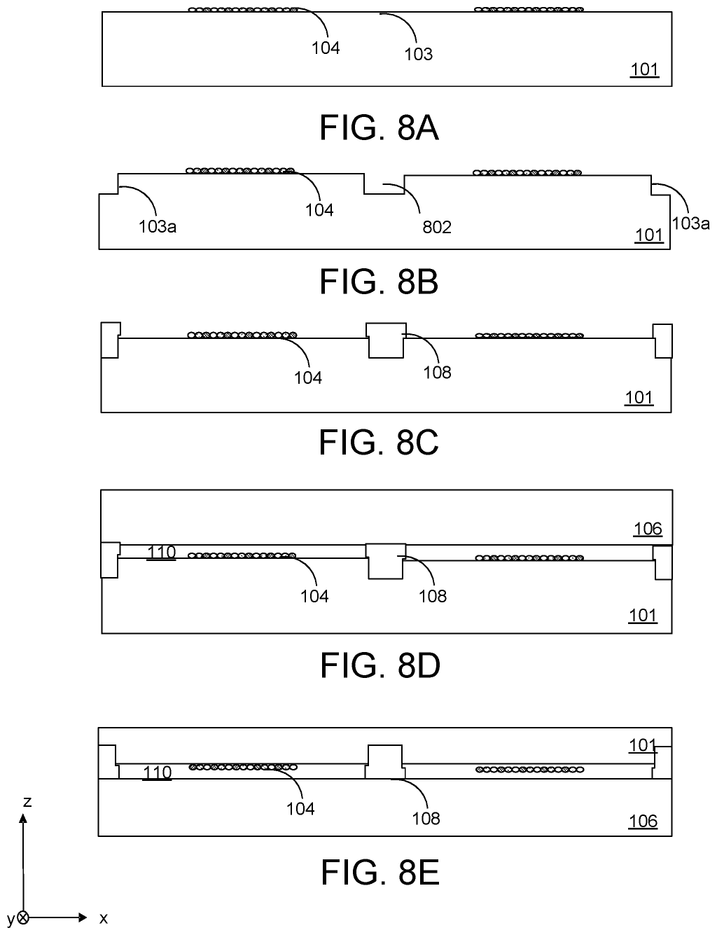

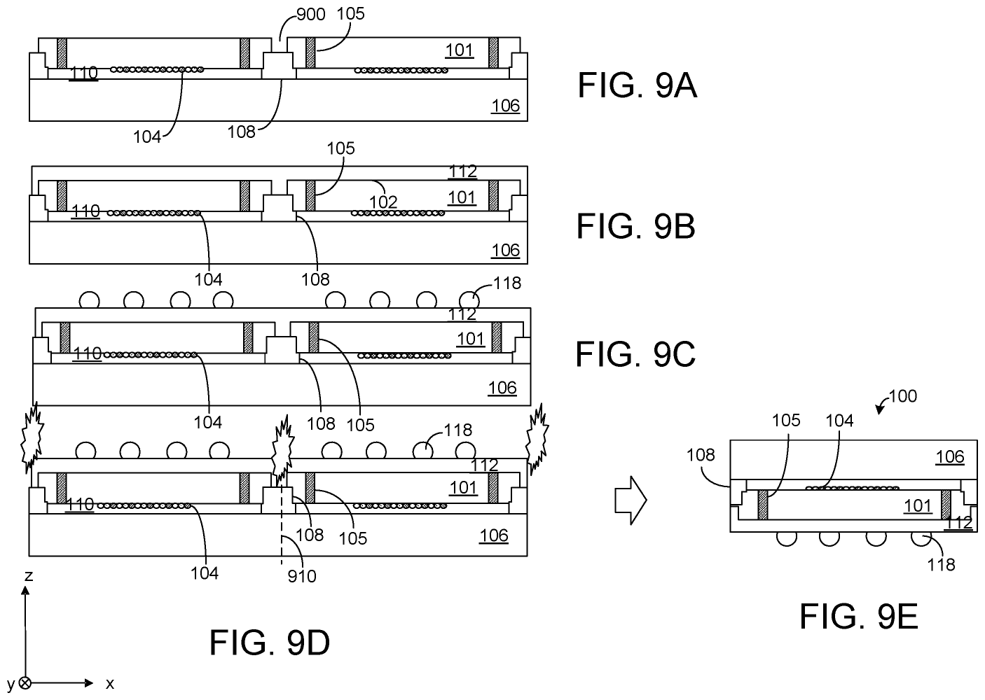

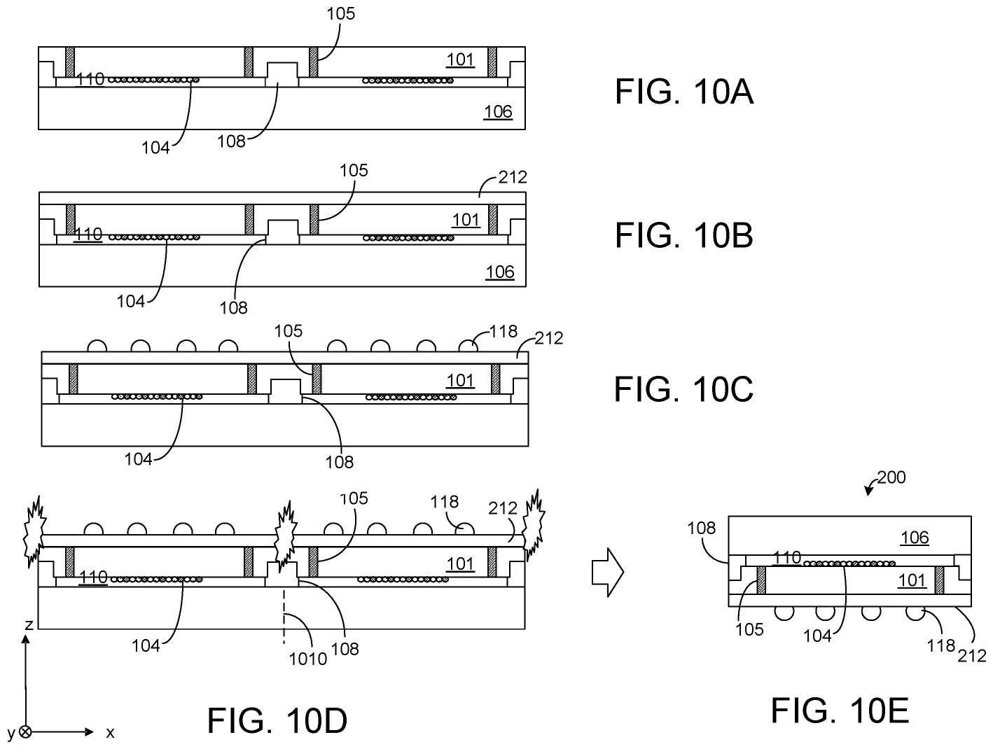

FIG. 7 is a flow chart illustrating a method 700 for fabricating the optical sensor modules 100, 200, 300, and 400, in accordance with some implementations of the present disclosure. Operations 702-720 of the method 700 can be carried out to form various image sensor module structures, according to some implementations as described below with respect to FIGS. 8A-8E, with respect to FIGS. 9A-9E (optical sensor modules 100 and 300), or with respect to FIGS. 10A-10E (optical sensor modules 200 and 400). Operations of the method 700 can be performed in a different order, or not performed, depending on specific applications. It is noted that the method 700 may not produce a complete optical sensor module. Accordingly, it is understood that additional processes can be provided before, during, or after method 700, and that some of these additional processes may be briefly described herein.

At 702, the method 700 includes forming photosensors on a substrate, e.g. on the optical sensor die 101, or on the planar optical sensor die 301, according to some implementations as shown in FIG. 8A. In the example shown, the substrate is a silicon substrate. The photosensors can be provided on an image sensor chip, e.g., the active area 104. In some implementations, the active area 104 can be direct bonded to the upper surface 103 of the optical sensor die 101 using for example, an epoxy, polyimide tape, or other bonding agent. Similarly, the active area 104 can be bonded to the upper surface 303 of the planar optical sensor die 301.

At 704, the method 700 includes forming recesses, e.g., notches 802, in the upper surface 103 of the optical sensor die 101, according to some implementations as shown in FIG. 8B. Alternatively, recesses in the form of grooves or pairs of grooves can be formed in place of the notches 802. Formation of the recesses at designated singulation points serves as a pre-scoring operation that can facilitate singulation and reduce breakage later, during the singulation process. Upon singulation of individual CSPs, the notches 802 will form a stepped surface profile 103a at upper corners of each CSP. In some implementations, the notches 802 can be formed by, for example, etching, or by a laser grooving process, and/or a partial wafer sawing process that uses a reduced down force to cut through a portion, but not all, of the silicon substrate. The notches 802 can be formed outside a seal ring (not shown) that surrounds and protects the active area 104. Different notch designs, e.g., deeper notches, or pairs of grooves, can be formed in the planar optical sensor die 301 as shown in FIG. 3 to create a structure in which a portion of the sidewall 314 will be exposed following singulation, and in the optical sensor die 301 as shown in FIG. 4, to expose the sidewall 314 after thinning and singulation.

At 706, the method 700 includes filling the recesses, e.g., the notches 802, with an insulator, that is, a non-conductive material, to form the dam 108, according to some implementations as shown in FIG. 8C. In some implementations, the insulator, e.g., the filling material, can be an epoxy molding compound (EMC), or another epoxy material, or another thermally curable or ultraviolet (UV) curable material, e.g., polyimide. In some implementations, the non-conductive material of the dam 108 can be both thermally non-conductive and electrically non-conductive. The filling material is intended to prevent moisture from entering the optical sensor module 100, or to form a wall that mitigates moisture penetration. In some implementations, the process used to fill the notches 802 can be a molding process such as injection molding, a photolithography process, or a dispensing process. In a dispensing process, the filling material may be dispensed in a liquid form and spun onto the silicon wafer so that it deposits in the notches 802. A subsequent thermal (e.g., baking) or UV curing (e.g., UV light exposure) process may be used to harden the dam 108. After the notches 802 are filled, an additional amount of the filling material may be formed over the notch to form a T-shaped dam 108. A masking layer can be used to pattern the filling material of the dam 108 that extends above the notch. The height of the dam 108 can be selected so as to define a desired height of the air cavity 110 above the active area 104. In some implementations, the height of the dam 108 above the upper surface 103 is in a range of about 10 μm to about 200 μm. In some implementations, the material that fills the notches 802 below the upper surface 103 of the optical sensor die 101 can be a different material from the material of the dam 108 that extends above the upper surface 103. In some implementations, filling the notches 802 and forming the dam that extends above the upper surface 103 can be two separate processing operations, or they can be combined into a single operation.

At 708, the method 700 includes bonding the transparent lid 106 to the wafer, e.g., to the dams 108, according to some implementations as shown in FIG. 8D. Placing the transparent lid 106 forms the air cavity 110 between a lower surface of the transparent lid 106 and the upper surface 103 of the optical sensor die 101 so that the transparent lid 106 is suspended above the active area 104. In some implementations, a bonding tool can be programmed to dispense a liquid adhesive to coat upper surfaces the dams 108 using e.g., an epoxy or other bonding material, The transparent lid 106 can then be placed on the dams 108, and pressure can be applied to the transparent lid 106.

Alternatively, in some implementations, the bonding process used to attach the transparent lid 106 can be a lamination process, e.g., a process in which the transparent lid 106 is coated with a photosensitive adhesive film and is heated to form a bonded laminate. In some implementations, the photosensitive adhesive film can have a thickness of about 30 μm to about 100 μm. The bonding process can include patterning the photosensitive adhesive film to remove the photosensitive adhesive film from the transparent lid 106 wherever the transparent lid 106 will not be in contact with the dam 108, and to retain the photosensitive adhesive film wherever the transparent lid 106 will be in contact with the dam 108. In some implementations, the patterning process may resemble a conventional photolithography process used to pattern a photoresist mask, e.g., exposing the photosensitive adhesive film to light through an optical mask, and then applying a developer to remove exposed, or unexposed, portions of the photosensitive adhesive film, depending on a chemical composition of the photosensitive adhesive film. Thus, the photosensitive adhesive film can be patterned directly without use of a contact mask or an etching operation. The lamination process serves to partially harden, or solidify, the photosensitive adhesive film. Following lamination, however, the photosensitive adhesive film is not fully cured so that it retains its adhesive properties and can still act as a bonding agent.

In some implementations, the bonding agent can be a photosensitive adhesive film made of a solid, partially pre-cured material that can be dry laminated to the dam 108 instead of, or in addition to, applying the photosensitive adhesive film to the transparent lid 106. Because the adhesive is not fully cured, it can still retain sufficient bonding properties so that, in response to applying heat and/or pressure, the adhesive film may become flowable so as to adhere the dams 108 to the transparent lid 106.

At 710, the silicon substrate can be thinned, according to some implementations as shown in FIG. 8E. First, the stack shown in FIG. 8D is inverted as shown in FIG. 8E so that the optical sensor die 101 is shown as being suspended over the transparent lid 106. Following inversion, the optical sensor die 101 is supported by the T-shaped dam 108, while the lower surface 102 of the optical sensor die 101 can then be thinned using, for example, a grinding process or a chemical-mechanical planarization (CMP) process. In some implementations, the optical sensor die 101 is thinned to a thickness in a range of about 50 μm to about 500 μm. In some instances, thinning the silicon substrate may not be necessary, depending on the relative dimensions of the silicon substrate and the device.

At 712, the through-silicon vias (TSVs) 105 are formed in the thinned optical sensor die 101 according to some implementations as shown in FIG. 9A. The TSVs can be formed using a via etching process by masking the lower surface 102 and etching through the full thickness of the optical sensor die 101. The TSVs can then be filled with a metal, e.g., copper, aluminum, or alloys thereof, using, for example, a metal deposition process or a plating process, depending on the metal and the TSV depth. The metal filling the TSVs 105 can then be polished to be co-planar with the lower surface 102.

At 714, the solder mask 112 is formed at the lower surface 102 of the optical sensor die 101, according to some implementations as shown in FIG. 9A and FIG. 9B. The solder mask 112 is a layer of polymer that protects circuitry at the lower surface 102 of the optical sensor die 101. The solder mask 112 includes surface openings (not shown) allowing the solder balls 118 to connect to metallization at the lower surface 102. In some implementations, the solder mask 112 can include a redistribution layer (RDL) of metal interconnects that provides a fan-out from micro-scale or nano-scale metallization at the lower surface 102 to the macro-scale solder balls 118. The solder mask material then forms an insulating structure of the RDL.

To form the wrap-around solder mask 112 in the optical sensor module 100, or in the optical sensor module 300, first, trenches 900 are formed in the optical sensor die 101 above the dams 108 as shown in FIG. 9A. The trenches 900 can be formed using a via etch process that etches silicon with selectivity to the insulator material of the dams 108. The solder mask material can then be deposited in the trenches 900. After the trenches 900 are filled, the solder mask can further be deposited on the lower surface 102 to a thickness in a range of about 3 μm to about 50 μm.

Alternatively, to form the planar solder mask 212 in the optical sensor module 200, or in the optical sensor module 400, the solder mask material can be deposited to the desired thickness directly after completing formation of the TSVs 105, as shown in FIGS. 10A and 10B.

At 716, solder balls 118 are formed, according to some implementations as shown in FIGS. 9C and 10C. The solder balls 118 can be deposited as molten solder on the underside of the solder mask 112 as shown in FIG. 9C, or on the underside of the solder mask 212, as shown in FIG. 10C. The solder balls 118 will harden as they cool.

At 718, the method 700 includes singulating the stack shown in FIG. 9D into the individual optical sensor modules 100 shown in FIG. 9E, according to some implementations. Alternatively, the method 700 can include singulating the stack shown in FIG. 10D into the individual optical sensor modules 200 shown in FIG. 10E, according to some implementations. Singulation may include a process of cutting, sawing, or scoring the stacked structure shown in FIG. 9D along singulation boundaries 910. Or, singulation may include a process of cutting, sawing, or scoring the stacked structure shown in FIG. 10D along singulation boundaries 1010. The singulation boundaries 910 and 1010 are singulation cut lines that are aligned with midpoints of the dams 108. The singulation technique can be similar to that used to singulate a semiconductor wafer into individual dies or chips. If the transparent lid 106 used is made of a polymer material, a different or modified singulation technique may be employed to achieve a clean cut along the singulation boundaries 910, 1010.

At 720, the method 700 includes a curing operation, according to some implementations. The curing operation can simultaneously cure the adhesive film used to bond the transparent lid to the dam 108, and the insulating material of the dam 108. In some implementations, the cure operation can be accomplished by applying a thermal treatment that includes heating the optical sensor module 100 to a temperature of about 300 degrees C., and desirably less than 320 degrees C. Additionally, or alternatively, the cure operation for some compositions of the photosensitive adhesive film and/or the dam 108 may include exposure to ultraviolet (UV) light. Although it may be possible, desirable, or necessary, depending on the materials used, to execute the curing operation directly after the bonding procedure at 708, in some implementations, the curing operation may be more effective following singulation when a larger surface area of the dam 108 is exposed.

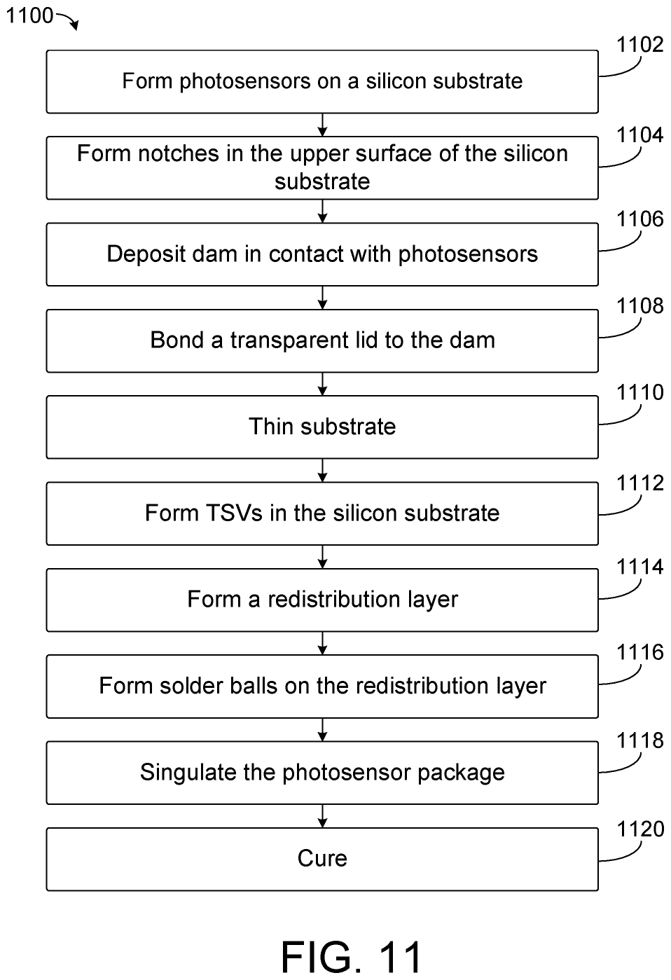

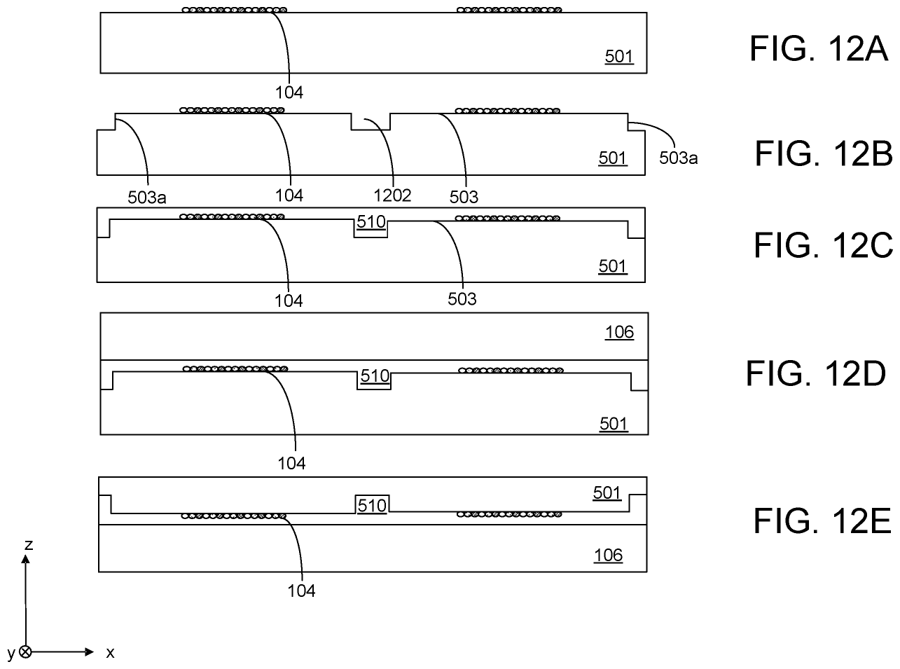

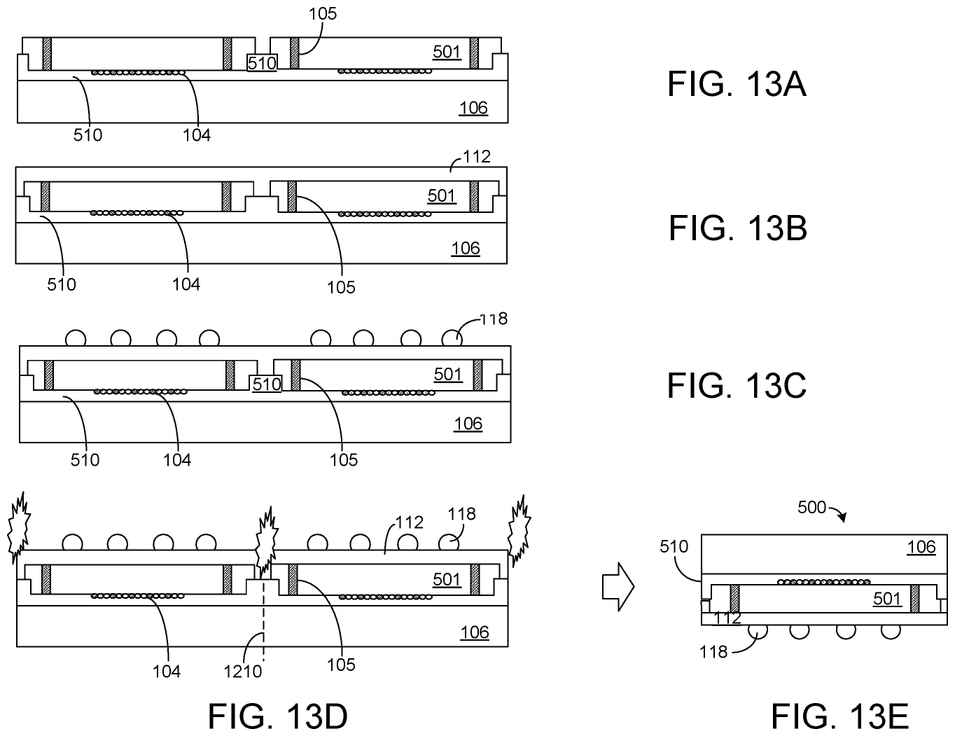

FIG. 11 is a flow chart illustrating a method 1100 for fabricating the optical sensor module 500, in accordance with some implementations of the present disclosure. Operations 1102-1120 of the method 1100 can be carried out to form various implementations of the optical sensor module 500, according to some implementations as described below with respect to FIGS. 12A-12E and FIGS. 13A-13E. Operations of the method 1100 can be performed in a different order, or not performed, depending on specific applications. It is noted that the method 1100 may not produce a complete optical sensor module 500. Accordingly, it is understood that additional processes can be provided before, during, or after method 1100, and that some of these additional processes may be briefly described herein.

The operations 1102 and 1104 are similar to the operations 702 and 704, respectively, as described above, in which the active area 104 is part of the silicon optical sensor die 501 as shown in FIG. 12A and grooves or notches 1202 are formed in the upper surface 503 of the optical sensor die 501 as shown in FIG. 12B. The notches 1202 will form a stepped surface profile 503a at upper corners of each CSP. In some implementations, the depth of the notches 1202 is as much as about half the substrate thickness.

At 1106, the notches 1202 can be filled with an insulator material to form a dam 508, according to some implementations as shown in FIG. 12C. In some implementations, instead of using the material that forms the dams 108, the notches 1202 can be filled with the solder mask material. After the notches 1202 are filled, the insulator is further deposited so as to form a planar surface on the dam 508 with a thickness above the upper surface 503 that covers the active area 104. The thickness of the dam 508 can be in a range of about 10 μm to about 200 μm. The dam 508 thus takes the place of the air cavity 110 in the optical sensor module 100.

At 1108, the transparent lid 106 is bonded to the planar surface of the dam 508, according to some implementations as shown in FIG. 12D. Because the bonding surface of the transparent lid 106 and the bonding surface of the dam 508 are planar and no patterning is needed, the bonding operation can be a direct bond using, for example, a spin-on adhesive material that coats the surface of the dam 508.

The operations 1110-1120 are similar to the operations 710-720 as described above, in which the bonded, stacked structure shown in FIG. 12D is inverted; the optical sensor die 501 is thinned as shown in FIG. 12E; the through-silicon vias 105 are formed as shown in FIG. 13A; trenches are formed in the optical sensor die 501 down to the dam 508 as shown in FIG. 13A; the RDL process is completed to form the solder mask 112 as shown in FIG. 13B; solder balls 118 are attached to the underside of the solder mask 112 as shown in FIG. 13C; and the stacked wafer structure shown in FIG. 13D is singulated along a cut line 1210 to form individual optical sensor modules 500 laterally protected by dams 508, as shown in FIG. 13E.

As described above, the dam 108 fabricated by the method 700 and the dam 508 fabricated by the method 1100 serve two important functions within the optical sensor modules 100 and 500, respectively. First, the dams surround active areas of the optical sensor dies 104 to protect the image sensors from moisture and associated contamination. Second, the dams each provide a solid, non-compressible foundation of uniform height that allows the transparent lid 106 to remain substantially co-planar with the upper surface of the substrate that supports the active area 104.

It will be understood that, in the foregoing description, when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, top, bottom, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor device processing techniques associated with semiconductor substrates including, but not limited to, for example, silicon (Si), silicon carbide (SiC), gallium arsenide (GaAs), gallium nitride (GaN), and/or so forth.

While certain features of the described implementations have been illustrated as described herein, many modifications, substitutions, changes, and equivalents will now occur to those skilled in the art. For instance, features illustrated with respect to one implementation can, where appropriate, also be included in other implementations. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

1. An apparatus, comprising:
a photodetector on a substrate;
a transparent lid spaced apart from the photodetector by a gap;
a notch formed in an upper surface of the substrate;
a plurality of electrical contacts coupled to a lower surface of the substrate;
a through-silicon via being used to electrically couple the photodetector to the plurality of electrical contacts;
a solder mask in contact with a lower surface of the substrate; and
an insulating material disposed between the transparent lid and the substrate, the insulating material filling the notch to form a dam.

2. The apparatus of claim 1, wherein the notch is formed at a singulation point in the substrate.

3. The apparatus of claim 1, wherein a pair of grooves is formed at a singulation point in the substrate.

4. The apparatus of claim 1, wherein the electrical contacts are solder balls.

5. The apparatus of claim 1, wherein the solder mask includes a redistribution layer.

6. The apparatus of claim 1, wherein the solder mask wraps around three sides of the substrate.

7. The apparatus of claim 1, wherein the transparent lid is spaced apart from the photodetector by an air cavity.

8. The apparatus of claim 7, wherein the insulating material is configured to prevent moisture from entering the air cavity.

9. The apparatus of claim 1, wherein the transparent lid is spaced apart from the photodetector by an insulating layer.

10. A method, comprising:
forming a photosensor on a silicon substrate;
forming notches in a top surface of the silicon substrate at designated singulation points;
filling the notches with an insulating material;
extending a height of the insulating material above the top surface;
bonding a cover glass to the insulating material to form a bonded structure;
forming a through-silicon via in the silicon substrate;
forming a redistribution layer in contact with the silicon substrate;
forming a plurality of electrical contacts coupled to the redistribution layer and electrically coupling the plurality of electrical contacts to the photosensor by the through-silicon via; and
singulating the bonded structure based on the designated singulation points.

11. The method of claim 10, wherein the redistribution layer wraps around three sides of the silicon substrate.

12. The method of claim 10, wherein forming the redistribution layer includes etching trenches in the silicon substrate near the designated singulation points and filling the trenches with a solder mask material.

13. The method of claim 10, further comprising thinning the silicon substrate prior to forming the through-silicon vias.

14. The method of claim 10, further comprising forming an air cavity between the cover glass and the silicon substrate.

15. A method, comprising:
pre-scoring a photosensor package by forming a recess in a silicon substrate;
disposing a moisture barrier in the recess; and
singulating the photosensor package from the silicon substrate.

16. The method of claim 15, wherein singulating the photosensor package includes cutting through a transparent lid.

17. The method of claim 15, wherein disposing a moisture barrier in the recess includes filling the recess with an epoxy material.

18. The method of claim 15, further comprising over-filling the recess with the moisture barrier to support a transparent lid spaced apart from the silicon substrate by an air cavity.

19. The method of claim 15, wherein pre-scoring the photosensor package includes forming a notch in the silicon substrate.

20. The method of claim 15, wherein pre-scoring the photosensor package includes forming a pair of grooves in the silicon substrate.
